(19) United States
(12) Patent Application Publication
(10) Pub. No.: US 2010/0051502 A1
(43) Pub. Date: Mar. 4, 2010

(54) CARRIER HAVING INTEGRAL DETECTION AND MEASUREMENT OF ENVIRONMENTAL PARAMETERS

(75) Inventors: ERIC CYBULSKI, St. Paul, MN (US); Ashley E. Engelhardt, Greenwood, IN (US); Orlin B. Knudson, St. Paul, MN (US); Jon A. Kirschhoffer, St. Paul, MN (US); Vladimir Kraz, Santa Cruz, CA (US); James G. Carlson, St. Paul, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/204,570

(22) Filed: Sep. 4, 2008

(51) Int. Cl. H01L 21/673; B65D 85/90; H05K 9/00

(52) U.S. Cl. 206/710; 206/723; 206/459.1; 220/756; 29/402.01; 700/121

(57) ABSTRACT

A carrier includes an enclosure for storing articles sensitive to electrostatic discharge (ESD) and a replacement component that is affixed to the enclosure as an integral component of the carrier. The replacement component includes a housing that provides an enclosure for a device having a sensor for sensing one or more environmental parameters. At least one of the sensed environmental parameters is an ESD parameter.

### TECHNICAL FIELD

The invention relates to monitoring environmental parameters and, more particularly, to monitoring environmental parameters in a manufacturing process.

### BACKGROUND

An electrostatic discharge (ESD) can permanently damage sensitive electronic devices. For example, semiconductor wafers, magnetic heads for disk drives, integrated circuits, and other electronic components and circuits may be damaged by ESDs. For devices that are not damaged by the ESD, the occurrence of an ESD can still disrupt the operation of an electronic circuit. In non-electronic applications, such as powder handling, ESD can cause a fire and lead to damage.

Reticles used for photolithography in a semiconductor manufacturing process can be extremely sensitive to ESD exposure. A reticle is an insulative plate of quartz glass with conductive chrome traces that represent a layout of an integrated circuit (IC). The spacing between these traces is extremely small. The smaller the geometry of the IC to be produced using the reticle, the smaller this spacing becomes. When a reticle is exposed to an electrostatic field, induced voltage can create a discharge between two adjacent traces. This discharge can create a permanent bridge between these traces (i.e., an electrical short) or create a discontinuity in a trace (i.e., an open circuit). Such reticle defects are repeatedly patterned onto multiple wafers, producing defective ICs. Replacement of a reticle itself may cost over $100,000 and the additional loss due to production of defective silicon and missing a deadline can be devastating. As the latest technology continues to decrease minimum trace widths, the occurrences of damage due to ESD in semiconductor manufacturing are becoming increasingly more common. ESD events not only impact process yields by damaging a semiconductor reticle, but also can damage expensive optical proximity correction and phase shift masks that may be difficult to replace.

### SUMMARY

In general, a carrier is described that includes an enclosure for storing articles sensitive to electrostatic discharge (ESD) and a component (e.g., a handle) affixed to the enclosure so as to serve as an integral component of the carrier. The component is formed so as to provide an additional housing that provides an entire enclosure for a device having a sensor for sensing one or more environmental parameters. At least one of the sensed environmental parameters is an ESD parameter. The carrier may be sized to conform to an industry-standard form factor for carriers of article sensitive to ESD, such as wafers, masks, or photolithography reticles for use in the semiconductor manufacturing process. The component may be a replacement component that is affixed to the reticle's enclosure at a position and orientation to replace an original component of the carrier without substantially changing the form factor of the carrier. For example, the replacement component may include a replacement handle that provides an entire enclosure for the device and is affixed to the carrier at a position and orientation where an original handle of the carrier was positioned prior to removal of the original handle from the carrier.

An environment, such as a semiconductor manufacturing environment, is described that includes a system of a plurality of carriers (e.g., reticle carriers) for storing articles sensitive to electrostatic discharge (ESD), wherein each of the plurality of carriers includes a device having a sensor to sense the environmental parameters. The system also includes a plurality of radio frequency (RF) receiving devices such as RF routers configured to obtain data associated with the sensed environmental parameters from the devices of the plurality of carriers throughout the environment via wireless communications according to a wireless networking standard. The plurality of RF routers may, for example, communicate with a central coordinator unit via a wireless network. For example, the wireless network may be a Zigbee wireless mesh network or a network that conforms to the 802.15.4 standard. As the carriers traverse the environment, e.g., the semiconductor manufacturing environment, the plurality of RF routers collect and route the data obtained from the devices of the plurality of carriers to the central coordinator unit.

In some cases, the system may be used to locate and track the movements of the carriers through the environment and the location of ESD events within that environment. For example, each device may learn a unique identifier of the RF routers to which it is most closely positioned. The device may then incorporate that unique identifier of the parent RF router within the reporting data and/or when recording ESD events. Upon receiving the data from the carriers, the central coordinator uses the unique identifiers within each recorded event to log the locations of the reticle carriers and the ESD events that were recorded by the reticle carriers. At some positions within the environment, a device within a carrier may detect multiple signals transmitted by multiple RF routers, and may select the parent RF router from among the multiple RF routers by selecting one of the multiple RF routers having a strongest Received Signal Strength Indicator (RSSI).

The system may also include a plurality of radio frequency identification (RFID) portals positioned at various locations within the environment. The device includes an RFID chip that communicates with the plurality of RFID portals. The RFID chips may communicate with the RFID portals at a first frequency, which is different from a second frequency associated with the wireless networking standard used for communicating with the wireless network overlaying the RFID portals within the environment. For example, each of the devices may include a first integrated circuit for RFID communication at the first frequency and a second integrated circuit for communication at the second frequency according to the wireless networking standard. Each of the devices may be configured such that when the first integrated circuit detects an RFID signal transmitted at the first frequency by one of the plurality of RFID portals, a portion of the electrical components of the device wakes from a sleep state and transmits data associated with the sensed environmental parameters to one of the plurality of RF routers at a second frequency in accordance with the second wireless RF protocol by way of the second integrated circuit.

In one embodiment, a carrier comprises an enclosure for storing articles sensitive to ESD, and a replacement component that is affixed to the enclosure as an integral component of the carrier, wherein the replacement component comprises a housing that provides an enclosure for a device having a sensor for sensing one or more environmental parameters, wherein at least one of the environmental parameters comprises an ESD parameter.

In another embodiment, a handle for a carrier for storing items sensitive to environmental parameters, the handle comprising a housing and a device having a sensor for sensing one or more environmental parameters mounted entirely within the housing, wherein the handle is sized to replace an original handle of the carrier.

In a further embodiment, a method for retrofitting a carrier to include a device for sensing one or more environmental parameters comprises providing a carrier having an enclosure for storing articles sensitive to ESD, wherein the carrier includes an original component that is affixed to the enclosure as an integral component of the carrier, removing the original component from the carrier, and replacing the original component with a replacement component, wherein the replacement component includes a housing that provides an enclosure for the device having a sensor for sensing the one or more environmental parameters.

In yet another embodiment, an automation system for a semiconductor manufacturing environment comprises a plurality of carriers for storing articles used within the semiconductor manufacturing environment, and an automation system for gripping and moving the plurality of carriers, wherein the carriers conform to an industry-standard form factor required by the automation system. Each of the carriers comprises an enclosure for storing one or more of the articles, and a replacement component that is affixed to the enclosure as an integral component of the carrier. The replacement component comprises a housing that provides an enclosure for a device having a sensor for sensing one or more environmental parameters, wherein at least one of the environmental parameters comprises an ESD parameter. The replacement component is affixed to the enclosure at a position and orientation to replace an original component of the carrier without substantially changing the form factor of the carrier.

In a further embodiment, a carrier comprises an enclosure for storing articles sensitive to ESD, and a handle comprising a housing, and a device having a sensor for sensing one or more environmental parameters mounted entirely within the housing, wherein the handle is sized and positioned with respect to the enclosure to replace an original handle of the carrier.

In another embodiment, a system includes a plurality of carriers for storing articles sensitive to ESD, wherein each of the plurality of carriers includes a device having a sensor to sense one or more environmental parameters, wherein at least one of the environmental parameters comprises an ESD parameter, a plurality of radio frequency (RF) receiving devices, or a coordinator unit to which each of the plurality of RF receiving devices communicates by a wireless network according to a wireless networking standard. The plurality of RF receiving devices are configured to obtain data associated with the sensed environmental parameters from the devices of the plurality of carriers via wireless communications according to the wireless networking standard, and to route the data obtained from the devices of the plurality of carriers to the coordinator unit.

In a further embodiment, a system includes a plurality of carriers for storing articles sensitive to ESD, wherein each of the plurality of carriers includes a device having a sensor for sensing one or more environmental parameters, wherein at least one of the environmental parameters comprises an ESD parameter, and wherein the device includes a first integrated circuit for RFID communication at a first frequency and a second integrated circuit for communication at a second frequency according to a wireless networking standard. The system also includes a plurality of RFID portals configured to transmit a signal at the first frequency, and a plurality of RF receiving devices that serve as wireless access points within a wireless network in accordance with the wireless networking standard, wherein each of the plurality of RF receiving devices communicates by a wireless network with a coordinator unit. The devices are configured such that when the first integrated circuit detects a signal transmitted at the first frequency by one of the plurality of RFID portals, a portion of the device wakes from a sleep state and transmits data associated with the sensed environmental parameters to one of the plurality of RF receiving devices at a second frequency in accordance with the wireless networking standard by way of the second integrated circuit. The coordinator unit obtains the data associated with the sensed environmental parameters from the one of the plurality of RF receiving devices, and is coupled to a computing device configured to store the data obtained from the one of the plurality of RF receiving devices.

In yet another embodiment, a method comprises sensing one or more environmental parameters with a device having a sensor within a carrier for housing articles sensitive to ESD, wherein at least one of the environmental parameters comprises an ESD parameter, detecting a signal with a first integrated circuit of the device at a first frequency in accordance with a RFID standard, upon detecting the signal, waking a portion of the device from a sleep state, and transmitting data relating to the sensed environmental parameters at a second frequency in accordance with a wireless networking standard with a second integrated circuit of the portion of the device having been awoken from the sleep state.

In another embodiment, a semi-active RFID tag with continuous active sensing includes a sensor front end component that includes a sensor for continuously sensing for one or more environmental parameters, wherein at least one of the environmental parameters comprises an ESD parameter, a converter that converts the sensed environmental parameters to digital data, a microcontroller that stores the digital data to an external RAM memory and transfers the digital data from the external RAM memory to a tag memory, a battery that powers the sensor front end and a portion of the microcontroller, and an RF transceiver that detects a signal transmitted by an RFID portal and transmits the digital data from the tag memory to the RFID portal by an RFID communication in response to detecting the signal. The RF transceiver is powered by energy received from the signal transmitted by the RFID portal. The microcontroller is configured to operate in a sleep mode in which the microcontroller does not transfer the digital data from the external RAM memory to the tag memory when (i) the sensor does not detect one or more of the environmental parameters and (ii) the RF transceiver does not detect a signal transmitted by the RFID portal within a time period.

In a further embodiment, a method comprises receiving an RFID signal with an RFID circuit of an RFID tag, responsive to receiving the RFID signal, awakening a wireless networking circuit of the RFID tag, and upon awakening the wireless networking circuit, sending a wireless networking communication with the wireless networking circuit of the RFID tag.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram illustrating an example manufacturing system in which carriers are used to transport articles between manufacturing stations within a manufacturing process.

FIG. 2 is a block diagram illustrating an example system in which carriers follow a semiconductor fabrication process.

FIG. 3 is a block diagram illustrating in further detail an example carrier having an integrated device that communicates with an RFID portal and an RF router.

FIG. 4 is a block diagram illustrating an example table that includes rows of data entries recorded by a device associated with a carrier.

FIGS. 5A and 5B are block diagrams illustrating example semi-active RFID tags that senses sensory phenomena and communicates with an RFID portal by an RF wireless communication in accordance with the principles of the invention.

FIG. 6 is a perspective drawing illustrating an example reticle carrier that may be modified to include a replacement component having a device for sensing ESD parameters.

FIG. 7 is a perspective drawing illustrating an example replacement component that provides a housing that provides an entire enclosure for a device having a sensor for sensing environmental parameters, including ESD parameters.

FIG. 8 is a perspective drawing illustrating an exploded view of the replacement component of FIG. 7.

FIG. 9 is a perspective drawing illustrating a lid of the replacement component from a different perspective.

FIG. 10 is a perspective drawing illustrating a printed circuit board suspended inside of a bottom portion of the replacement component.

FIG. 11 is a perspective drawing illustrating an exploded view of another example embodiment of a replacement component.

FIG. 12 is a perspective drawing illustrating an example embodiment of a lid of a replacement component for a carrier.

FIG. 13 is a perspective drawing illustrating another example embodiment of a replacement component.

FIG. 14 is a perspective drawing illustrating an example charging base having a receiving member sized for receiving a replacement component so that a battery of the device within the replacement component may be recharged.

### DETAILED DESCRIPTION

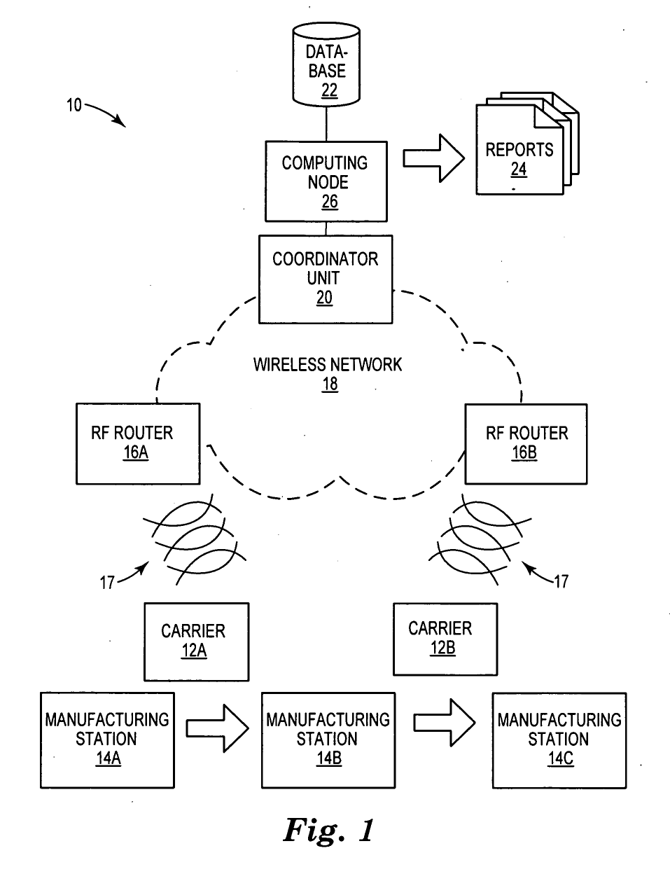

FIG. 1 is a block diagram illustrating an example system 10 in which carriers 12A-12B (“carriers 12”) are used to transport articles between manufacturing stations 14A-14C (“manufacturing stations 14”) within a manufacturing process. For example, the manufacturing process may be for manufacturing semiconductor wafers, and carriers 12 may be carriers to carry masks, reticles, wafers, or combinations thereof.

Semiconductor manufacturing processes may be highly automated so as to minimize human exposure to chemicals used during the processes. In a conventional automated semiconductor manufacturing system, an automation unit, such as a robotic arm or other mechanism, may be used at or between manufacturing stations 14 for transporting carriers 12. When the manufacturing station 14 is finished with the contents of the carrier 12, the automation unit may retrieve the carrier 12 from the manufacturing station and may return it to an assigned carrier storage location. A host computing system communicating with a control unit may control the operation of the automated manufacturing system.

To manipulate a carrier 12, the automation unit typically has a physical interface that engages the carrier 12 and allows the automation unit to convey and manipulate the orientation of the carrier 12. As a robotic arm, for example, the automation unit may include a gripper that grasps the selected carrier 12. Because the carriers 12 must be positioned in a precise manner for the robotic arm to grasp them correctly, the carriers 12 and the storage locations are constructed with exact dimensions. Accordingly, the carriers 12 of the manufacturing system typically have substantially similar, if not identical, form factors to be received by the interface of the automation unit, and such form factors may be defined by industry standards.

In accordance with the principles of the invention described herein, carriers 12 may be modified carriers that include devices having a sensor for sensing electrostatic discharge (ESD) that may occur at different stages within the semiconductor manufacturing process. As described in further detail below, carriers 12 may each include an enclosure for storing articles sensitive to ESD (e.g., reticles, wafers, masks), and an additional housing that encloses the device having the sensor. Moreover, the additional housing for holding the device may be provided by a replacement component that is affixed to the enclosure as an integral component of the carrier 12, that is, the replacement component belongs as part of the carrier 12 as a whole. The replacement component replaces an original mechanical component of the carrier. For example, the housing for holding the device may be provided internally within a replacement handle that replaces an original handle that has been removed from the carrier without interfering with the form factor required by the automation equipment. As another example, the housing may consist of a replacement bottom portion of the carrier 12 so as to provide a self-contained additional housing for holding the device.

The sensor may detect the presence and strength of ESD events within the manufacturing environment. For example, the sensor may monitor the presence of electrostatic fields, magnitude of electrostatic fields, polarity of electrostatic discharges, and magnitude of electrostatic discharges. Sensors of the device within the replacement component of the carrier may sense other environmental parameters in addition to ESD parameters, such as a temperature, a humidity level, an acceleration, an inclination, presence of a chemical, and presence of a particle (e.g., dust). In some cases, multiple sensors may be provided within the device for sensing the environmental parameters.

As illustrated in FIG. 1, system 10 includes a plurality of networked RF routers 16A-16B (“RF routers 16”). RF routers 16 may provide a wireless network 18 that envelops the manufacturing site so as to be continuously available over substantially all of the manufacturing site. Further, RF routers 16 may operate in accordance with a wireless networking protocol to connect RF routers 16 to a coordinator unit 20 of the wireless network 18 that collects data from each of the RF routers 16. For example, wireless network 18 may be a wireless network that conforms to a wireless networking standard. The wireless networking standard may be a non-RFID standard such as the Institute of Electrical and Electronics Engineers (IEEE) 802.15.4 standard, the IEEE 802.11 standard, or a Zigbee standard. In some aspects, the wireless network may, for example, be a Zigbee network or a Dust network. Further, in some embodiments, wireless network 18 may be a mesh network in which the network nodes are all connected to each other. A mesh configuration may provide extended ranges. Other network topologies may also be employed, such as a point-to-point network, a star network, or a cluster tree network. Repeaters may be used to extend the range of wireless network 18. RF routers 16 may be wireless access points (WAPs) that communicate with devices integrated with carriers 12A and 12B by way of wireless communications 17. RF routers 16 communicate with coordinator unit 20 by wireless network 18. The devices integrated with carriers 12 may communicate with RF routers 16 by way of wireless communications in a number of ways, such as on a continuous basis, on a periodic basis, or on an event-driven basis. In one embodiment, for example, the devices integrated with carriers 12 may be woken up programmatically at a defined period of time. Alternatively, as described below, the devices may be polled to provide stored data at particular points in a fabrication process.

The devices within carriers 12 may be, for example, measuring and recording devices, and may convert the sensed environmental events into data, and communicate with RF routers 16 according to the wireless networking standard to transmit the data obtained by the sensor to coordinator unit 20 by way of RF routers 16. The devices may store information including one or more serial numbers (e.g., reticle serial numbers) and process tracking information.

Coordinator unit 20 may comprise a radio having an RF transceiver or antenna, and is coupled to a computing node 26. Computing node 26 may comprise a central processing unit (CPU), a personal computer (PC), or other computing device. Coordinator unit 20 collects the data from each of carriers 12 via base stations 16 and computing node 26 stores the information in a database 22. Computing node 26 may include data manager software for managing the collected data. Computing node 26 may also present a user interface by which a user can request and view reports 24 generated by the data management software. For example, sensors provided within carriers 12 may sense an ESD event proximate one or more of manufacturing stations 14. Computing node 26 may generate reports 24 providing analysis of the data indicative of events monitored and recorded by the devices. Such reports 24 may include, for example, results from an analysis related to the presence, location and strength of ESD events. The reports may identify where and when an ESD event has occurred relative to the manufacturing stations 14 based on the information obtained from carriers 12 via RF routers 16.

The result presented in the reports 24 may include a comparison with targets to determine whether system 10 is performing properly within tolerance levels, whether preventive maintenance should be performed, whether system parameters should be adjusted, whether certain areas of the manufacturing process are particularly susceptible to ESD, or to identify other problems. Such reports 24 permit detailed analysis and comparison of the operation of the system 10, and permit a corporate entity to view operation of a plurality of systems in a single report. Any or all of these reports 24 may be generated periodically (e.g., hourly, daily, weekly, monthly, annually, etc.) or on demand when requested by a service technician or corporate entity responsible for operation of system 10. These reports 24 provide a mechanism through which an ESD event may be promptly identified and located and corrective actions taken to remove any damaged components from carriers 12. This may also allow operators to prevent further ESD events from occurring by fixing problems on the manufacturing floor. Generation of reports 24 allows service technicians or corporate entities to provide long distance analysis of the process situation, identify potential for improvements, and make corrections remotely. The reports may include web pages, tables, graphs, text or other appropriate media to communicate the data.

Computing node 26 may also include other audible or visual indicators that may be used to indicate system status information. Computing node 26 may generate an alert indicating the occurrence of an ESD event. Computing node 26 may display various system parameters and/or reports on a graphical user interface. The user interface may allow a user or service technician to adjust various system parameters, or to install software updates. An external connection, such as a telephone, cell phone, or internet connection, allows computing node 26 to automatically generate and send outbound messages such as e-mails, voice mails, text messages, reports and the like to a service technician or corporate entity responsible for operation of the system 10. Database 22 may include names and contact information (e.g., email addresses and/or telephone numbers) to which to send alerts in case of detecting problems. In some embodiments, computing node 26 may generate a map of the manufacturing environment that indicates a location of the ESD event, and may present the map to a user by way of the user interface.

Although described for purposes of example with respect to a system for semiconductor manufacturing, the principles of the invention are not so limited, and may readily be applied to other systems for manufacturing and handling articles sensitive to ESD, such as magnetic heads for disk drives, integrated circuits, and other articles. In addition, the principles of the invention may be applied to any other process that requires monitoring of environmental parameters.

Examples of a device for measuring and recording environmental parameters are described in U.S. Pat. No. 6,614,235, entitled Apparatus and Method for Detection and Measurement of Environmental Parameters, the entire contents of which is incorporated by reference herein. Examples of a device for continuously monitoring ESD events are described in U.S. Pat. No. 6,563,319, entitled Electrostatic Discharges and Transient Signals Monitoring System and Method, the entire contents of which is incorporated by reference herein.

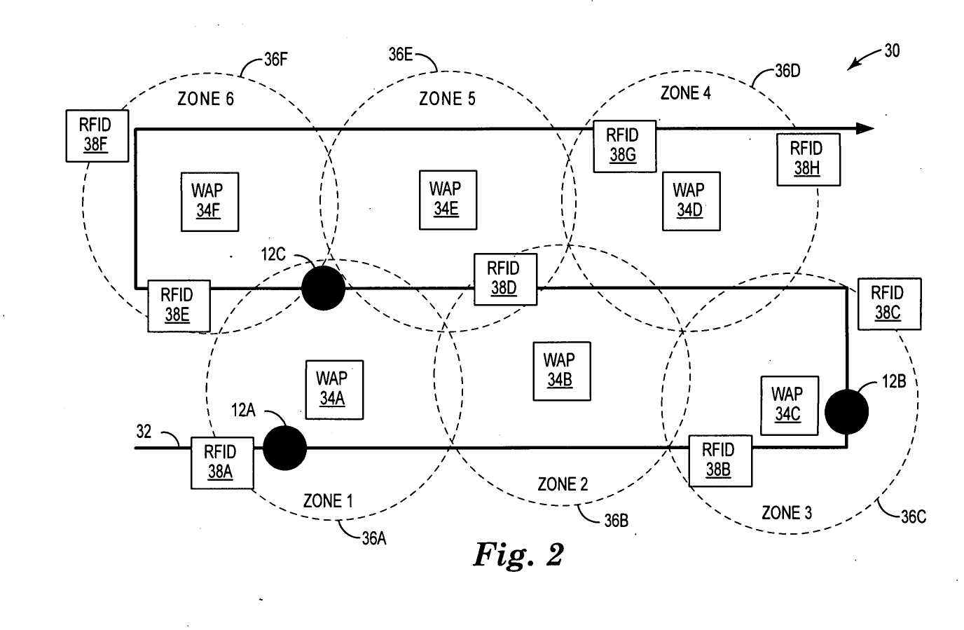

FIG. 2 is a block diagram illustrating an example system 30 in which carriers 12A-12C follow a semiconductor fabrication process 32 through a manufacturing environment. System 30 as illustrated in FIG. 2 provides an overhead view of semiconductor fabrication process 32 on a fabrication floor. Semiconductor fabrication process 32 may include one or more distinct fabrication stations (not shown) or may be a continuous process. System 30 includes a plurality of WAPs 34A-34F (“WAPs 34”), e.g., RF receiving devices such as RF routers. Each of WAPs 34 provides a wireless signal that creates a respective wireless zone 36A-36F around the positions of WAPs 34. For example, WAP 34A provides a signal that creates zone 36A, identified as “Zone 1.” Collectively, zones 36A-36F (“zones 36”) of WAPs 34 may provide a wireless network having a range that completely or nearly completely covers the footprint of semiconductor fabrication process 32 on the fabrication floor. For example, the wireless network may be a Zigbee network that conforms to the IEEE 802.15.4 standard. WAPs 34 may communicate with devices integrated with carriers 12 by way of wireless communications according to the 802.15.4 standard. Each of WAPs 34 may wirelessly communicate by way of the wireless network with a central coordinator unit, such as coordinator unit 20 of FIG. 1.

System 30 also includes a plurality of RFID portals 38A-38H (“RFID portals 38”) (labeled “RFID” in FIG. 2). RFID portals 38 may be placed at important locations in the semiconductor fabrication process 32, such as areas where ESD problems may be likely to occur. RFID portals 38 may continuously emit electromagnetic fields that energize RFID tags of devices that come into range of RFID portals 38. Alternatively, RFID portals 38 may be triggered to emit the electromagnetic fields based on a sensor (e.g., an infrared sensor) or a proximity switch. Although shown for purposes of example as having RFID portals 38A-38H, system 30 may include more or fewer RFID portals than are shown.

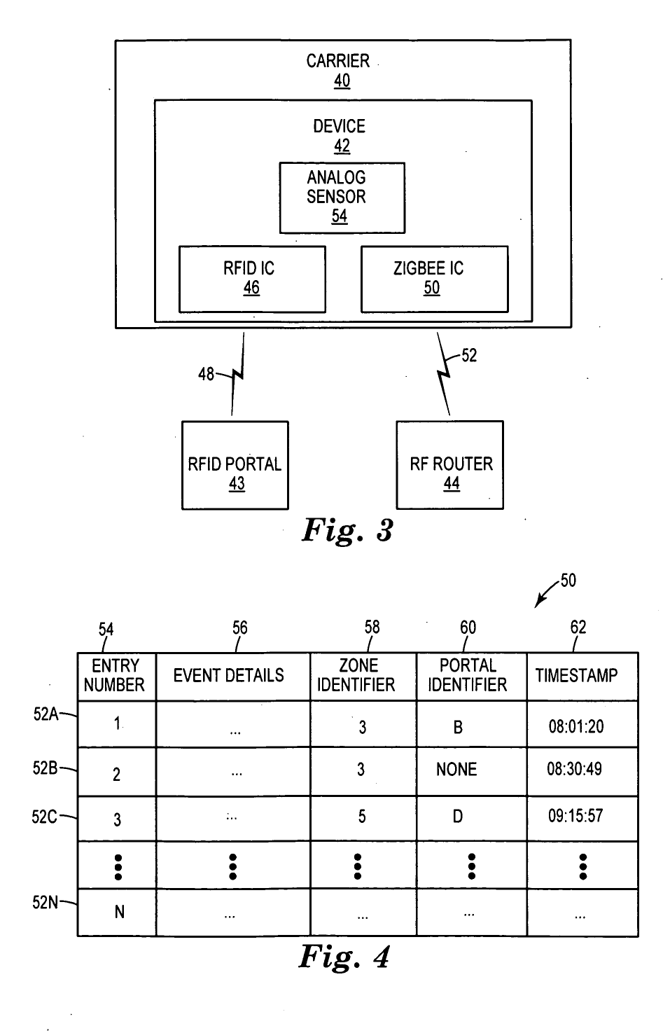

FIG. 3 is a block diagram illustrating in further detail an example carrier 40 having an integrated device 42 that communicates with an RFID portal 43 and an RF router 44 (i.e., a WAP). As illustrated in FIG. 3, device 42 includes an RFID integrated circuit (IC) 46 for communicating with RFID portals 43 by RFID communications 48 at a first frequency, and a Zigbee IC 50 for communicating with RF router 44 by 802.15.4 communications 52 at a second frequency. The first frequency may be within a range of 13.56 MHz to 960 MHz, for example, and the RFID communications may conform to an RFID standard. For example, the first frequency may be 915 MHz. The second frequency may be, for example, 2.45 GHz. Analog sensor 54 continuously senses for environmental parameters, such as ESD parameters.

In the embodiment of FIG. 3, Zigbee IC 50 may be configured to operate in a default sleep state, i.e., a low-power state in which power is not delivered to at least a portion of the Zigbee IC. When the carrier 12 comes within range of RFID portal 43, RFID IC 46 is powered by the electromagnetic field of the RFID portal 43. Upon being powered, RFID IC 46 provides an output signal to wake up Zigbee IC 50, i.e., to cause the Zigbee IC 50 to transition to a fully powered state. Zigbee IC 50 then transmits data associated with the sensed environmental parameters stored within a memory (not shown) of device 42 to RF router 44 by a communication 52 at the second frequency in accordance with the 802.15.4 standard. In some cases, device 42 may transmit the data at both the second frequency and the first frequency. Upon receiving the communication 52 from the Zigbee IC 50, RF router 44 may send an acknowledgement message to the Zigbee IC 50 acknowledging receipt of the communication. The acknowledgement message may conform to the 802.15.4 standard. When Zigbee IC 50 receives the acknowledgement message, Zigbee IC 50 may then return to the sleep state. If Zigbee IC 50 fails to receive an acknowledgement message from RF router 44 within a time period, Zigbee IC 50 may resend the communication. In this manner, the device 42 can conserve power by keeping Zigbee IC 50 in a default sleep state. Instead of Zigbee IC 50 being continuously awake, Zigbee IC 50 generally exists in a sleep state and is strategically awoken by RFID portals 43 to transmit the stored data at key points in the fabrication process.

Although device 42 is shown for purposes of example in FIG. 3 as including a Zigbee IC 50, device 42 may include any wireless networking circuit, i.e., a non-RFID circuit that is awoken by an RFID circuit when the device 42 receives an RFID signal. The wireless networking circuit may then send a wireless networking communication to communicate the stored data. For example, the wireless networking circuit may be a 802.11 circuit that sends an 802.11 communication, i.e., a communication conforming to the IEEE 802.11 standard.

Referring again to FIG. 2, the use of RFID portals 38 may allow for finer-grained location tracking of carriers 12 on the fabrication floor, which may help to locate problems when an ESD event is detected by the devices integrated with carriers 12. For example, when one of the devices integrated with a carrier 12 detects an ESD event, the event may be logged by the device. At some later time, an RFID portal 38 triggers wakeup of the Zigbee IC 50 of the device, and the data is retrieved from the devices by one of WAPs 38 of a zone 36 in which the carrier 12 is presently located.

An example process will now be described with respect to FIGS. 2 and 3. For example, carrier 12A may be placed onto semiconductor fabrication process 32, e.g., manually or by way of automation equipment. Initialization of the device integrated within carrier 12A may be performed by an operator using a reticle management software running on coordinator unit 20, for example. For example, coordinator unit 30 may transmit control signals to carrier 12A via WAP 34A to set parameters and give instructions.

At the start of transit, WAP 34A may read a carrier identifier (ID) provided by an RFID tag of the device within carrier 12A, and WAP 34A may provide this information to coordinator unit 20. For example, an RFID IC 46 of a device 42 of carrier 12A may sense a field emitted by RFID portal 38A, which may cause RFID IC 46 to awaken Zigbee IC 50 to communicate the carrier ID to WAP 34A.

A reticle may be physically placed within carrier 12A. An ID of the reticle may be entered into a user interface of computing node 26 coupled to coordinator unit 20. Computing node 26 may logically associate an ID of the reticle with the carrier ID obtained via WAP 34A by creating an entry in database 22. An operator of computing node 26 may reset a memory associated with analog sensor 54 by sending a command to the device via WAP 34A. The operator may configure the sensitivity of the device depending on a sensitivity of the reticle to ESD. For example, the operator may set thresholds for sensed parameters. Carrier 12A then proceeds within semiconductor fabrication process 32. When carrier 12A is out of range of RFID portal 38A, Zigbee IC 50 returns to the default sleep state. Device 42 detects, measures, and records data associated with ESD occurrences during transportation of the reticle. Analog sensor 54 continuously senses for ESD parameters or other parameters. For example, analog sensor 54 may sense static voltage and ESD events. When analog sensor 54 detects something, a microcontroller of device 42 (not shown) turns on and determines whether what analog sensor 54 detected was indeed an ESD occurrence. If the sensed phenomenon was an ESD occurrence, the microcontroller records data corresponding to the parameters sensed by in the memory. ESD events can be gated by static voltage to localize discharges.

Analog sensor 54 may be powered by a battery of the device 42. Some time later, carrier 12A may arrive at a data checkpoint within semiconductor fabrication process 32. For example, when carrier 12A comes within range of RFID portal 38B, RFID IC 46 is energized by the electromagnetic field emitted by RFID portal 38B and, in turn, wakes up Zigbee IC 50 for transmission of data stored within a memory of the device 42. This data may include the carrier ID, the reticle ID, and data recorded by analog sensor 54. The data may be stored in database 22, and may provide an “ESD passport” that provides information about the reticle's trip through semiconductor fabrication process 32. Reticle management software of computing node 26 may analyze the ESD passport data, and may report on the likeliness that damage may have occurred to the reticle during transit. The reticle management software may issue recommendations based on the analysis, such as whether to proceed with using the reticle for printing wafers, whether to send the reticle for inspection before printing. The reticle management software also analyzes cumulative damage to the reticle and projects a reticle replacement schedule.

When the Zigbee IC 50 of a device 42 associated with a carrier is woken up, the Zigbee IC 50 may sense a signal from one or more of WAPs 34, depending on whether the carrier 12 is located within a single one of zones 36 or multiple overlapping zones. For example, when a carrier 12 comes into range of RFID portal 38D of system 30 (FIG. 2), the Zigbee IC 50 associated with that carrier 12 is awoken by the RFID IC 46 and may detect multiple signals transmitted by multiple WAPs 34, such as WAP 34B and WAP 34E. Zigbee IC 50 selects one of WAPs 34B and 34E as a parent WAP. Zigbee IC 50 may determine which one of the WAPs 34 is the closest in an RF sense, and select that WAP as the parent WAP. For example, Zigbee IC 50 may select as its parent the one of WAPs 34B and 34E having a stronger Received Signal Strength Indicator (RSSI).

Zigbee IC 50 may learn a unique identifier of the parent WAP 34, and may store the unique identifier to memory in association with other data recorded at the time of learning the unique identifier. For example, WAPs 34 may be Zigbee routers that have an IEEE Extended Organizationally Unique Identifier (EUI), which is a globally unique address that is eight bytes long. Zigbee IC 50 may learn the parent WAPs EUI and incorporate the EUI into a message sent to the coordinator unit 20. When coordinator unit 20 obtains the data from the memory of the device 42, coordinator unit 20 may use the recorded unique identifier of the parent WAP 34 to identify an approximate location of a carrier 12 affected by an ESD event recorded in association with the identifier. For example, coordinator unit 20 may use the unique identifier of the parent to determine a zone that the ESD event occurred in by referencing database 22, such as Zone 5 in the case of WAP 34E. This information can be used to identify one or more carriers 12 that may have been affected by an ESD event. In some embodiments, carriers 12 may have devices 42 with attenuated receive strength or transmit strength to increase location finding precision. By decreasing the communication range of the devices, a device 42 can only associate itself to a parent WAP that is physically close enough to communicate with. In some embodiments, device 42 may automatically reduce its communication range until only a single WAP 34 is detected.

RFID IC 46 may also store in the memory an identifier of the RFID portal 38D that RFID IC 46 detected. Computing node 26 may use the identifier of the RFID portal 38 to provide even more specific location finding of ESD events. For example, if an ESD event was recorded in conjunction with a WAP identifier of 34E (Zone 6), and an RFID portal identifier of 38E, this provides more fine-grained location tracking information than simply an indication of Zone 6 alone.

In some embodiments, a wireless networking protocol other than Zigbee may be employed. In this case, device 42 may include in the data transmitted using the wireless networking protocol the RSSI values of all of neighboring WAPs 34 that device 42 has detected. The wireless networking protocol may be modified to allow this information to be communicated. Computing node 26 may then determine the strongest RSSI value and derive the location of device 42 based on this information.

FIG. 4 is a block diagram illustrating an example table 50 that includes rows 52A-52N of data entries recorded by a device 42 associated with a carrier. For example, table 50 is an exemplary logical representation of certain data stored by device 42, e.g., within a memory of the device 42. In addition, table 50 may comprise a portion of database 22 of FIG. 2, e.g., after the data has been provided to coordinator unit 20 from one of the devices 42. Table 50 includes an entry number column 54 in which a number is assigned to the entry, and an event details column 56 in which the event details are recorded. For example, the event details may include ESD parameters relating to an ESD event, or other recorded parameters such as temperature, humidity, and the like. Table 50 also includes a zone identifier column 58 that indicates in which zone the event details were recorded, a portal identifier column 60 that indicates an identifier of an RFID portal from which a signal was detected at the time the entry was made, and a timestamp column 62 that records a time the entry was made.

In some embodiments, Zigbee IC 50 may by default continually search for signals from WAPs 34 instead of existing in a default sleep state. As shown in FIG. 4, entry 52B (corresponding to entry number 2) shows that a WAP signal was detected, from which the device determined it was in zone 3, but that no portal identifier was detected at the time of entry. Assume that table 50 includes data stored by a device 42 integrated with carrier 12B in system 30 of FIG. 2, and that entry 2 includes event details indicating an ESD event. Based on the information in entries 1-3, it can be determined that the ESD event occurred at a location on the semiconductor fabrication process 32 within zone 3 and somewhere after carrier 12B left the range of RFID portal 38B, but where the carrier 12B was not within the range of RFID portal 38C. Thus, the presence of the RFID portals 38 may allow a location of an ESD event to be identified more precisely than simply a zone determination. The timestamps may also be useful in pinpointing a location along the fabrication process.

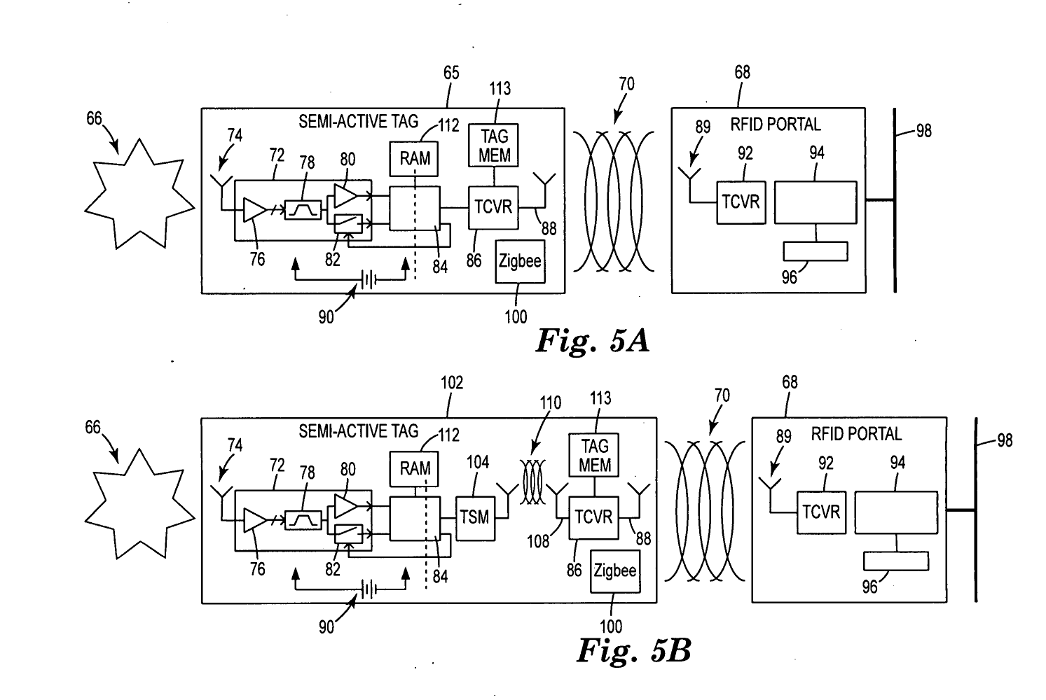

FIGS. 5A and 5B are block diagrams illustrating example semi-active RFID tag 65 and semi-active RFID tag 102, respectively, that sense sensory phenomena 66 and communicate with an RFID portal 68 by an RF wireless communication 70 in accordance with the principles of the invention. Semi-active RFID tag 65 is one example of a device that may be integrated with a carrier for storing articles sensitive to ESD. As shown in FIG. 5A, semi-active tag 65 includes a sensor front end (SFE) component 72 having a sensor antenna 74 for sensing sensory phenomena 66. SFE component 72 includes an amplifier 76 that amplifies the analog signal obtained by sensor antenna 74, and a filter 78 that filters the signal, a comparator 80, and a zero-order hold 82. Amplifier 76, filter 78, comparator 80, and zero-order hold 82 may together comprise an analog-to-digital converter that converts the sensed environmental parameters to digital data. Semi-active tag 65 further includes a microcontroller 84 and a transceiver 86 (“TCVR”) having an antenna 88 for communicating with an antenna 89 of RFID portal 68 by way of RF communications. RFID portal 68 includes a transceiver 92 and a microcontroller 94, and a memory 96. RFID portal may be connected to a coordinator unit (not shown) by an Ethernet connection 98.

SFE component 72 and a first portion of microcontroller 84 may be powered by an on-board power source, such as battery 90. Transceiver 86 and a second portion of microcontroller 84 may be powered by the RFID portal 68. The dotted line that extends through microcontroller 84 illustrates this division in power. In semi-active tag 65, SFE 72 may require power beyond that anticipated to be received from RFID portal 68 for the continuous monitoring of sensory phenomena 66 (e.g., electromagnetic or electrostatic events). In addition, access to the power of RFID portal 68 may not be continuously available in a semiconductor fabrication process, so another power source must be used (e.g., an on-board power source or power-harvesting circuitry). The power consumption of the entire tag may be limited, so it is advantageous to have antenna 88 and transceiver 86 powered externally when in the presence of RFID portal 68. The first portion of microcontroller 84 may consist of that portion of microcontroller 84 that records the data received from SFE 72 to an external RAM memory 112. This first portion of microcontroller 84 may remain awake at all times and be powered by battery 90, or may awaken only upon SFE 72 detecting the sensory phenomena 66.

When semi-active tag 65 is not in the presence of RFID portal 68, those components that rely on RFID portal 68 for power may be placed in a sleep mode. For example, a second portion of the microcontroller 84 that transfers data stored to external RAM memory 112 to tag memory 113 associated with transceiver 86 may be configured to operate in a sleep mode when sensor antenna 74 does not detect one or more of the environmental parameters (i.e., sensory phenomena 66) and transceiver 86 does not detect a signal transmitted by RFID portal 68 within a time period. The second portion of microcontroller 84 may be awakened upon detection of a signal from RFID portal 68. In other words, when transceiver 86 detects a signal from the RFID portal 68, microcontroller 84 is configured to operate in a fully awake mode in which both the first and second portions of microcontroller 84 are awake. A microcontroller having various sleep modes may be used to conserve tag power consumption, such as the MSP430F1611 available from Texas Instruments Incorporated. When SFE 72 detects sensory phenomena 66, microcontroller 84 may initially write data obtained by sensor antenna 74 to external RAM memory 112, and may subsequently transfer the data from external RAM memory to a tag memory 113 associated with transceiver 86 of semi-active tag 65 via a wired connection. The tag memory 113 may be non-volatile memory, so that the data is maintained even when the transceiver 86 and the second portion of the microcontroller 84 are no longer powered by an RFID portal 68.

FIG. 5B illustrates a semi-active tag 102 that also includes a Tagsense nanomodule 104 coupled to the microcontroller 84 and an external RAM memory 112 coupled to the microcontroller 84. Tagsense nanomodule 104 (“TSM”) includes an antenna 106 for transmitting data from tag memory 113 to an antenna 108 of transceiver 86 of semi-active tag 102 by an RF wireless communication 110. For example, microcontroller 84 may provide sensed data from external RAM memory 112 to Tagsense nanomodule 104, which wirelessly transmits the data by RF wireless communication 110 within semi-active tag 102 to a tag memory 113 of transceiver 86, which stores the data. This wireless transmission may be powered by battery 90 or by energy from RFID portal 68. When an RFID portal 68 is detected by transceiver 86, antenna 88 may communicate the data stored in tag memory 113 of transceiver 86 to antenna 89 of RFID portal 68 by an RF communication 70.

Semi-active tags 65 and 102 may also include a Zigbee circuit 100 for communication with receiving devices in a Zigbee wireless network, as described above. In some embodiments, when transceiver 86 detects the presence of RFID portal 68, transceiver 86 or microcontroller 84 may awaken the Zigbee circuit 100 from a default sleep state, and Zigbee circuit 100 may transmit the data to a parent RF receiving device (not shown) of a wireless network by a wireless transmission, such as in accordance with the 802.15.4 standard. Upon receiving an acknowledgement from the parent RF router that the transmission was received, Zigbee circuit 100 may return to the sleep state. The external RAM memory 112 may be a non-volatile external memory such as the FM25L256 by Ramtron. The transceiver 86 may be a Chipcon CC1100 transceiver available from Texas Instruments Incorporated.

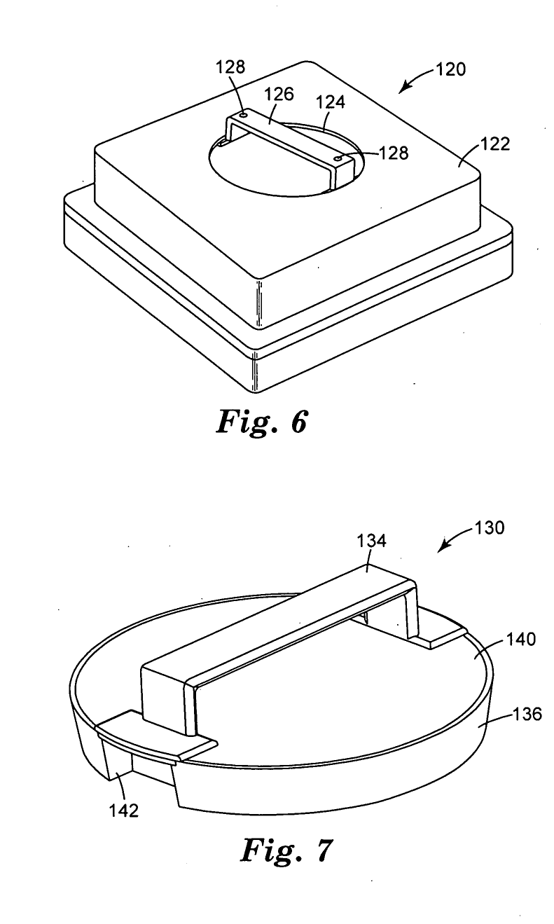

FIG. 6 is a perspective drawing illustrating an example original reticle carrier 120 that may be modified to include a replacement component having a device for sensing ESD parameters. Carrier 120 includes a housing 122 for storing reticles, wafers, masks, or other articles sensitive to ESD that are used in a semiconductor fabrication process. Carrier 120 includes a recess 124 over which an original handle 126 is mounted by screws 128 on either end of the handle. Carrier 120 is designed to be handled by an automated system and may be sized to conform to an industry-standard form factor.

FIG. 7 is a perspective drawing illustrating an example replacement component 130 that provides an internal housing that provides an entire enclosure for a device having a sensor for sensing environmental parameters, including ESD parameters. For example, the housing may provide an enclosure for containing device 42 of FIG. 3 or semi-active tags 65 and 102 of FIGS. 5A and 5B. Replacement component 130 may replace original handle 126 of carrier 120 when handle 126 has been removed from carrier 120. Replacement component 130 includes a replacement handle 134 that replaces the original handle 126 of carrier 120. The bottom portion of replacement component 130 is sized to fit within recess 124 of carrier 120. Replacement component 130 is designed to fit within recess 124 of carrier 120 without any modifications to the existing design of carrier 120. In this manner, existing carriers may be retrofitted to include the device for sensing ESD parameters. When replacement component 130 is fitted within recess 124, handle 126 may be structured so as not to extend beyond a point at which original handle 126 extended from carrier 120. As a result, replacement component 130 is integrated with carrier 120 without substantially changing the form factor of carrier 120. Placing replacement component 130 on the outside of carrier 120 protects the contents of carrier 120 and may make removal of replacement component 130 from carrier 120 easier (e.g., for recharging a rechargeable battery of the device).

In the example of FIG. 7, the housing of replacement component 130 includes two portions that provide a hermetically sealed enclosure to house and protect the device. Replacement component 130 provides a housing that protects the device from damage or contamination by particles. The device (not shown) may be formed on a printed circuit board (not shown) housed within the enclosure of replacement component 130. As described above, the device includes a sensor for sensing environmental parameters including ESD parameters. For example, an ESD parameter may include a magnitude of a detected ESD event and an amount of static voltage. Other environmental parameters sensed by the sensor may include a temperature, a humidity level, an acceleration, an inclination, a presence of a chemical, and a presence of a particle (e.g., dust).

The device includes a data logging device within the replacement component 130 that collects data from the sensor and records the collected data into a memory of the device. The device also includes a radio frequency (RF) element that transmits the collected data to an external device via an RF transmission, and a wireless communication component, wherein the RF element internally transmits the collected data to the wireless component within the replacement component via a first RF transmission, and wherein the wireless communication components transmits the collected data to a device external to the replacement component via a second RF transmission.

A lid portion 140 fits on top of a bottom portion 136 of the housing. In the example of FIG. 7, lid portion 140 is formed as a single piece that integrates the handle 134. The bottom portion 136 includes indents 142 below endpoints of the replacement handle 134, which allow replacement component 130 to fit with protrusions present within recess 124 of carrier 120. The housing may also include means for affixing the replacement component 130 to the enclosure of carrier 120, wherein the means for affixing is arranged on the enclosure to affix the replacement component 130 at the same position and orientation of an original component to the carrier. For example, the protrusions of recess 124 may include clearance holes for receiving screws 128 that affix handle 126 to carrier 120. When original handle 126 is removed from carrier 120, e.g., by unscrewing the screws 128, replacement component 130 may be fitted into recess 124. In some embodiments the original screws 128 may be used to affix replacement component 130 to carrier 120 through clearance holes in the lid portion 140 and the bottom portion 136 of replacement component 130 (not shown). Replacement handle 134 is therefore affixed at the same position with respect to carrier 120 as was original handle 126. Replacement handle 134 may in some cases be affixed at the same orientation with respect to carrier 120 as original handle 126, or in other cases may be affixed at a different orientation with respect to carrier 120, such as at a position rotated 90 degrees or at another angle. Even when replacement handle 134 is oriented differently with respect to carrier 120 than the original handle 126, the original screws 128 and clearance holes may still be used. When replacement component 130 is affixed to carrier 120 by screws or other means, replacement component 130 forms an integral component of the carrier 120. For example, as shown in FIG. 7, replacement component 130 provides a replacement handle 134 for carrier 120. Replacement handle 134 is configured to be grasped by an automated system to carry carrier 120.

Replacement component 130 may be a hermetically sealed, waterproof enclosure for the device. Replacement component 130 may be constructed from a non-conductive material that allows replacement component 130 to be easily wiped clean, such as a plastic material.

Replacement component 130 is also removable from carrier 120, i.e., by removing the screws that affix replacement component 130 to carrier 120 and lifting replacement component 130 from recess 124 using replacement handle 134. This allows the battery of device 42 to be recharged.

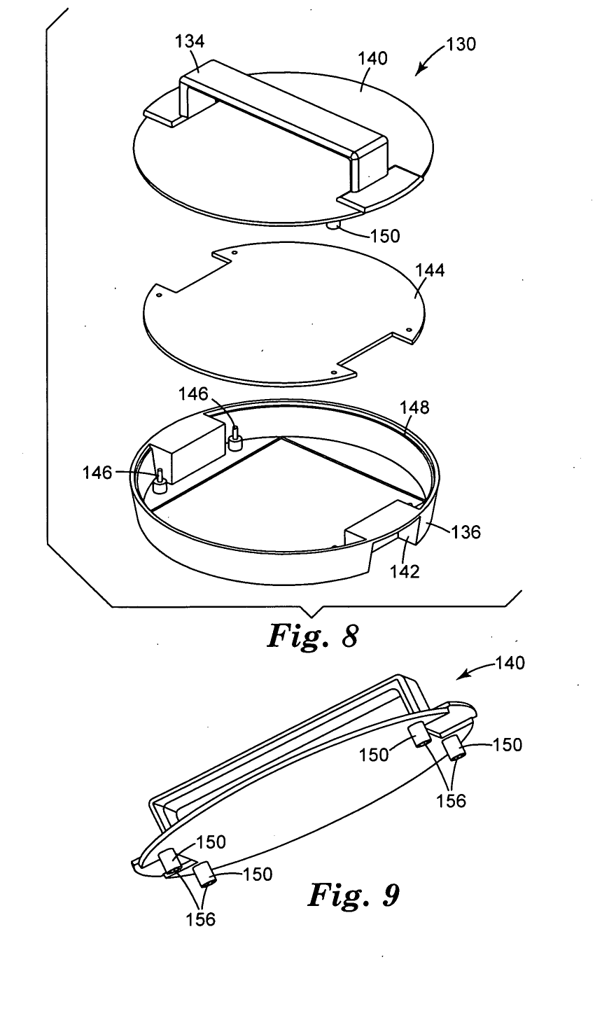

FIG. 8 is a perspective drawing illustrating an exploded view of the replacement component 130 of FIG. 7. As illustrated in FIG. 8, replacement component 130 includes lid 140 having replacement handle 134, bottom portion 136, and a printed circuit board 144. The device (not shown) may be provided on printed circuit board 144. Printed circuit board 144 may be secured by four mounting bosses 146 inside of bottom portion 136 (only two of mounting bosses 146 are shown in FIG. 8).

FIG. 9 is a perspective drawing illustrating lid 140 from a different perspective. The four upper mounting boss receiving members 150 are shown on the underside of lid 140.

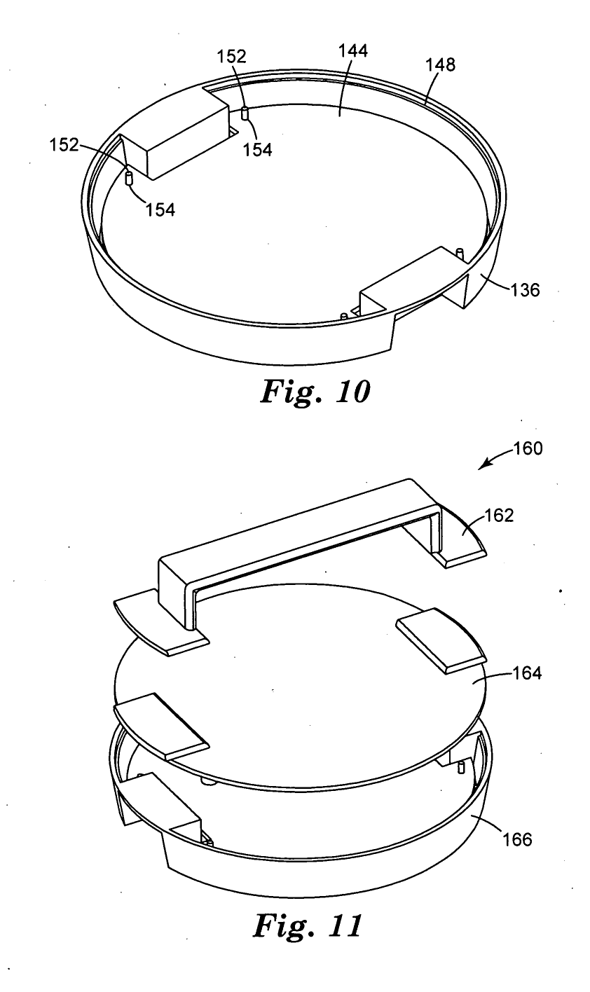

FIG. 10 is a perspective drawing illustrating printed circuit board 144 suspended inside of bottom portion 136 on mounting bosses 146. Narrow tips 152 of mounting bosses 146 extend through holes 154 in printed circuit board 144. Mounting bosses 146 allow printed circuit board 144 to be suspended above the inner bottom surface of the housing of replacement component 130. Suspending printed circuit board 144 above the inner bottom surface of the housing may help protect the device from being damaged when carrier 120 is being transported.

When assembled, printed circuit board 144 rests on mounting bosses 146, and lid 140 rests on a ridge 148 along an inside rim of bottom portion 136. The enclosure of replacement component 130 may be sealed along ridge 148. Lid 140 includes four upper mounting boss receiving members 150 provided at positions that line up with mounting bosses 146 of bottom portion 136. Upper mounting boss receiving members 150 may have cylindrical hollow openings 156 configured to receive the cylindrical tips of mounting bosses 146. When lid 140 is resting on ridge 148 of bottom portion 136, cylindrical hollow openings 156 of upper mounting boss receiving members 150 and mounting bosses 146 mate to secure printed circuit board 144 in place suspended within the enclosure formed by bottom portion 136 and lid 140. Upper mounting boss receiving members 150 press on a top side of printed circuit board 144 and mounting bosses 146 press on a bottom side of printed circuit board 144. Mounting bosses 146 may be molded into the enclosure. The use of mounting bosses 146 eliminates the need for removable parts for securing and protecting printed circuit board 144, such as springs. In some cases, mounting bosses 146 may comprise standoffs that are threaded inserts. More or fewer than four mounting bosses 146 and mounting boss receiving members 150 may be used to secure printed circuit board 144 in place within the enclosure.

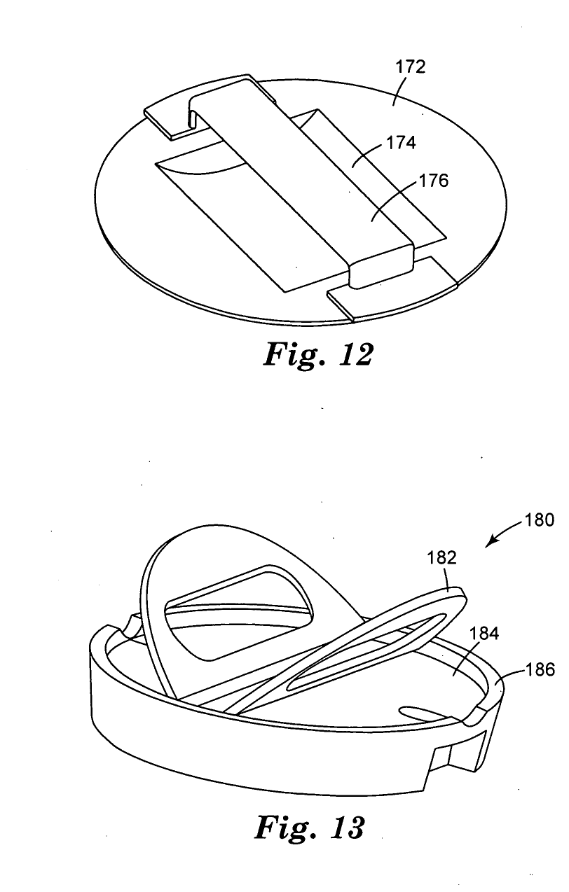

FIG. 11 is a perspective drawing illustrating an exploded view of another example embodiment of a replacement component 160. Replacement component 160 is substantially similar to replacement component 130 described above, except that replacement handle 162 may be formed as a separate piece from lid 164 that fits on bottom portion 166. Providing a replacement component 160 having a separable replacement handle 162 may allow greater flexibility than a replacement handle affixed to or integrated with the lid, since the separable replacement handle 162 may be changed out with a different replacement handle as needed.

FIG. 12 is a perspective drawing illustrating another example embodiment of a lid 172 of a replacement component for carrier 120. Lid 172 includes an indent 174 below handle 176. The presence of indent 174 may allow for handle 176 to have a shorter profile so that the replacement component better fits a particular form factor of carrier 120, while still allowing handle 176 to be easily grasped. In addition to being moved by an automated system carrier 120 may at times be carried by a person. The person carrying carrier 120 may be wearing gloves in a clean room environment to protect from contamination of carriers 120 and the enclosed reticles, wafers, or masks. Indent 174 may make it easier to grasp handle 176.

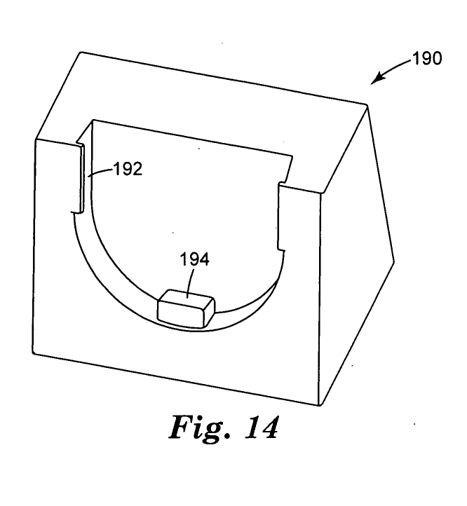

FIG. 13 is a perspective drawing illustrating another example embodiment of a replacement component 180. Replacement component 180 is substantially similar to replacement component 130 described above, except that replacement handle 182 of replacement component 180 has two halves and may include hinge members (not shown) that allow the two halves of replacement handle 182 to be folded upwards for grasping. When not in use, the two halves of replacement handle 182 fold down and rest within a recess 184 formed within lid 186 so that the handle 182 is flush with the top of lid 186. Providing a replacement component 180 having replacement handle 182 may allow for a larger enclosure for the device, and may allow carriers 120 having integrated replacement component 180 to be stacked on top of one another.

FIG. 14 is a perspective drawing illustrating an example charging base 190 having a receiving member 192 sized for receiving a removable replacement component of the reticle carrier so that a battery of the device within the replacement component may be easily recharged and interrogated via a data link with a host computer. A software upgrade may be performed by a data exchange via the data link. For example, a replacement component such as one of replacement components 130, 160, and 180 described above may be removed from carrier 120 and entirely placed onto receiving member 192. Charger base 190 includes an electrical connector 194 having one or more connections for mating with a recharging element positioned at a corresponding location on an exterior surface of the replacement component. In this manner, the housing of the replacement component need not be opened and the device need not be removed in order for the battery to be recharged.

Although the replacement component providing a housing for the device is described for purposes of example as including a replacement handle, in other embodiments, the replacement component may replace other components of the original carrier consistent with the principles of the invention. As one example, the replacement component may be a replacement member of the carrier that is sized to replace an original bottom surface of the carrier so as to form an integral component of the carrier. As another example, the replacement component may be a replacement member of the carrier that is sized to replace an original side surface of the carrier so as to form an integral component of the carrier. Alternatively, the replacement component could replace a component located inside housing 122 of carrier 120.

Various embodiments of the invention have been described. These and other embodiments are within the scope of the following claims.

1. A carrier comprising:
an enclosure for storing articles sensitive to electrostatic discharge (ESD); and
a replacement component that is affixed to the enclosure as an integral component of the carrier,
wherein the replacement component comprises a housing that provides an enclosure for a device having a sensor for sensing one or more environmental parameters, wherein at least one of the environmental parameters comprises an ESD parameter.

2. The carrier of claim 1, wherein the replacement component is affixed to the enclosure at a position and orientation to replace an original component of the carrier that has been removed from the carrier.

3. The carrier of claim 1, wherein the carrier is sized to conform to an industry-standard form factor for carriers of article sensitive to ESD, and
wherein the replacement component is affixed to the enclosure at a position and orientation to replace an original component of the carrier without substantially changing the form factor of the carrier.

4. The carrier of claim 1, wherein an outer surface of the enclosure of the carrier defines a recess, and wherein the replacement component is positioned within the recess.

5. The carrier of claim 4, wherein the replacement component is affixed to the enclosure at a position and orientation within the recess where an original component of the carrier was positioned prior to removal of the original component from the carrier.

6. The carrier of claim 1, wherein the replacement component comprises a replacement handle for the carrier, and wherein the replacement handle provides an entire enclosure for the device.

7. The carrier of claim 1, wherein the replacement component comprises a replacement member sized to replace an original bottom surface of the enclosure.

8. The carrier of claim 1, wherein the carrier is a carrier for use in a semiconductor manufacturing process, and wherein the articles comprise one of wafers, masks, and photolithography reticles for use in the semiconductor manufacturing process.

9. The carrier or claim 1, wherein the ESD parameter comprises one of a magnitude of a detected ESD event and an amount of static voltage.

10. The carrier of claim 1, wherein the one or more environmental parameters comprises one or more of a temperature, a humidity level, an acceleration, an inclination, and presence of a chemical.

11. The carrier of claim 1, wherein the device within the replacement component comprises:
a data logging device within the replacement component that collects data from the sensor; and
a memory within the replacement component, wherein the data logging device records the collected data into the memory.

12. The carrier of claim 11, wherein the device within the replacement component further comprises a radio frequency (RF) element, wherein the RF element transmits the collected data to an external device via an RF transmission.

13. The carrier of claim 1, further comprising a battery within the replacement component that provides power to the sensor,
wherein the battery is a rechargeable battery, and
wherein the housing of the replacement element includes a recharging element positioned on an exterior surface of the housing such that the battery may be recharged by placing the replacement component on a charger without opening the housing.

14. The carrier of claim 1, wherein the replacement component is removable from the carrier.

15. The carrier of claim 1, wherein the device within the replacement component further comprises a printed circuit board,
wherein the printed circuit board is mounted entirely within the housing, wherein the printed circuit board is positioned on mounts protruding from an interior of a bottom portion of the replacement component such that the printed circuit board avoids contact with the interior of the bottom portion of the replacement component when the printed circuit board is mounted within the housing, and
wherein the sensor is provided on the printed circuit board.

16. The carrier of claim 1, wherein the housing of replacement component comprises:
a bottom portion that forms a recess in which the sensor is positioned, and
a top portion that fits over the recess as a lid such that the sensor is enclosed by the bottom portion and the top portion, wherein the top portion includes a handle that replaces an original handle of the carrier,
wherein the bottom portion and the top portion include clearance holes positioned to align with holes within the enclosure for receiving mounting mechanism used to affix an original handle to the carrier, and
wherein the replacement component is affixed to the enclosure by the mounting mechanism by way of the clearance holes and the holes within the enclosure.

17. A handle for a carrier for storing items sensitive to environmental parameters, the handle comprising:
a housing; and
a device having a sensor for sensing one or more environmental parameters mounted entirely within the housing,
wherein the handle is sized to replace an original handle of the carrier.

18. A method for retrofitting a carrier to include a device for sensing one or more environmental parameters, the method comprising:
providing a carrier having an enclosure for storing articles sensitive to electrostatic discharge (ESD), wherein the carrier includes an original component that is affixed to the enclosure as an integral component of the carrier;
removing the original component from the carrier; and
replacing the original component with a replacement component, wherein the replacement component includes a housing that provides an enclosure for the device having a sensor for sensing the one or more environmental parameters.

19. An automation system for a semiconductor manufacturing environment comprising:
a plurality of carriers for storing articles used within the semiconductor manufacturing environment; and
an automation system for gripping and moving the plurality of carriers, wherein the carriers conform to an industry-standard form factor required by the automation system,
wherein each of the carriers comprises:
an enclosure for storing one or more of the articles; and
a replacement component that is affixed to the enclosure as an integral component of the carrier,
wherein the replacement component comprises a housing that provides an enclosure for a device having a sensor for sensing one or more environmental parameters, wherein at least one of the environmental parameters comprises an ESD parameter; and
wherein the replacement component is affixed to the enclosure at a position and orientation to replace an original component of the carrier without substantially changing the form factor of the carrier.

20. A carrier comprising:
an enclosure for storing articles sensitive to electrostatic discharge (ESD); and
a handle comprising:
a housing, and
a device having a sensor for sensing one or more environmental parameters mounted entirely within the housing,
wherein the handle is sized and positioned with respect to the enclosure to replace an original handle of the carrier.
